(19) United States
(12) Patent Application Publication
(10) Pub. No.: US 2018/0269677 A1
(43) Pub. Date: Sep. 20, 2018

(54) SEMICONDUCTOR ELEMENT DRIVING DEVICE

(71) Applicant: FUJI ELECTRIC CO., LTD., Kawasaki (JP)

(72) Inventor: Takuo YAMAMURA, Matsumoto (JP)

(73) Assignee: FUJI ELECTRIC CO., LTD., Kawasaki (JP)

(21) Appl. No.: 15/986,359

(22) Filed: May 22, 2018

Related U.S. Application Data
(63) Continuation of application No. PCT/JP2017/015987, filed on Apr. 21, 2017.

(30) Foreign Application Priority Data
Jun. 3, 2016 (JP) 2016-111983

(51) Int. Cl. H02H 7/122; H02H 1/00; H02M 1/08; H02M 7/5387; H03K 17/0812; G01R 19/165; G01R 31/26; G01R 31/42

(52) U.S. Cl. CPC H02H 7/122; H02H 1/0007; H02H 1/0061; H02M 1/08; H03K 19/20; H03K 17/08128; G01R 19/16547; G01R 31/2619; G01R 31/42; H02M 7/53871

(57) ABSTRACT

A semiconductor element driving device including: plural detection units configured to detect information necessary for protection operation for a semiconductor element included in a power conversion device; a protection signal generation unit configured to generate a protection signal having a pulse width different according to each of the plural detection units when the plural detection units detect the information necessary for the protection operation; a protection state monitoring unit configured to generate a protection state signal while any of the plural detection units is detecting the information necessary for the protection operation; and a signal output unit configured to output an alarm signal, the alarm signal changing from a first level to a second level when the protection signal and the protection state signal are input, and changing to an intermediate level between the first level and the second level when the input of the protection signal is stopped.

### CROSS REFERENCE TO RELATED APPLICATIONS AND INCORPORATION BY REFERENCE

This application is a continuation application filed under 35 U.S.C. § 111(a) of International Patent Application No. PCT/JP2017/015987, filed Apr. 21, 2017, which claims the foreign priority benefit under 35 U.S.C. § 119 of Japanese Patent Application No. 2016-111983, filed Jun. 3, 2016, the contents of which are incorporated herein by reference.

### TECHNICAL FIELD

The present invention relates, for example, to a semiconductor element driving device configured to drive a semiconductor element included in a power conversion device and have a protection operation identifying function.

### BACKGROUND ART

Recently, intelligent power modules (IPMs) have been drawing attention. The intelligent power modules are those in which semiconductor elements (power transistors such as IGBTs), driving circuits therefor, and protection circuits against abnormalities such as overcurrent in the semiconductor elements, low voltage of control power supply, and overheat are combined into a module as a single electronic component.

Additionally, there has also been a proposal for incorporating, besides a plurality of protection circuits that detect such abnormalities, a determination circuit (an output circuit) that externally outputs an alarm signal having a pulse width predetermined in accordance with the type of abnormality detected by each protection circuit in an intelligent power module (for example, see FIG. 3 of PTL 1).

By providing a determination circuit that outputs such an alarm signal, a control device side that controls a driving device, for example, an inverter control device can determine the type of abnormality occurring in a semiconductor element by detecting the pulse width of the alarm signal (for example, see PTL 2).

However, merely outputting an alarm signal as described above involves a problem where even when the abnormality in the semiconductor element is eliminated, the abnormality elimination cannot be detected. Thus, the present inventor has previously proposed a semiconductor element driving device configured to prevent the above defect and facilitate determination of an alarm signal output, typically, as a pulse signal train and detection of abnormality elimination (see PTL 3).

In accordance with an output of a detection circuit that has first detected abnormality, the semiconductor element driving device causes a low level voltage to be output by an amount corresponding to one pulse of an alarm signal upon start of abnormality detection, then returns to high level, and changes the signal output level of an output circuit to an intermediate level that represents protection cancellation for a certain period of time when the output of the abnormality detection signal is stopped.

Changing the signal output level of such an output circuit allows facilitation of determination of a plurality of alarm signals and also allows detection of elimination of abnormality in a semiconductor element, namely, detection of termination of protection operation.

### CITATION LIST

### Patent Literature

PTL 1: JP H11-17508 A
PTL 2: JP 2016-52178 A
PTL 3: JP 2014-103820 A

### SUMMARY OF INVENTION

### Technical Problem

In the semiconductor element driving device proposed in PTL 3, monitoring an output signal allows detection of a protection operation type at the start of a protection operation and also allows cancellation of the protection operation. However, during a period of time before output of a protection operation cancellation signal at which the output signal goes to the intermediate level after having returned to high level from the low level that represents the protection operation type, the output signal maintains the high level. Thus, in the period of time, it cannot be determined whether the protection operation state is continuing by merely detecting the output signal.

The present invention has been made by focusing on the unsolved problems of the conventional examples, and it is an object of the invention to provide a semiconductor element driving device that can facilitate determination as to whether protection operation is continuing by monitoring an alarm signal output from the driving device.

### Solution to Problem

In order to achieve the object mentioned above, according to an aspect of the present invention, there is provided a semiconductor element driving device including: a plurality of detection units configured to detect information necessary for protection operation for a semiconductor element included in a power conversion device; a protection signal generation unit configured to generate a protection signal having a pulse width different according to each of the plurality of detection units when the plurality of detection units detect the information necessary for the protection operation; a protection state monitoring unit configured to generate a protection state signal while any of the plurality of detection units is detecting the information necessary for the protection operation; and a signal output unit configured to output an alarm signal, the alarm signal changing from a first level to a second level when the protection signal and the protection state signal are input, and changing to an intermediate level between the first level and the second level when the input of the protection signal is stopped.

### Advantageous Effects of Invention

According to one aspect of the present invention, the type of a protection operation occurring in a semiconductor element can be easily determined by detecting the pulse width of an alarm signal at the first level. Additionally, detecting the second level of the alarm signal allows determination of continuation of the protection operation state.

### BRIEF DESCRIPTION OF DRAWINGS

FIG. 1 is a block diagram illustrating an overall schematic structure of a power conversion device to which the present invention is applied;

FIG. 2 is a block diagram illustrating a schematic structure of a driver circuit;

FIGS. 3A to 3C are signal waveform diagrams illustrating protection signal outputs from a protection signal generation unit; and

FIGS. 4A to 4J are signal waveform diagrams provided to describe operation of the present embodiment.

### DESCRIPTION OF EMBODIMENTS

An embodiment of the present invention will now be described with reference to the drawings. In the following description of the drawings, the same or similar reference signs are assigned to the same or similar constituent components.

In addition, the following embodiments exemplify devices and methods to embody the technical idea of the present invention, and the technical idea of the present invention does not limit the materials, shapes, structures, arrangements, and the like of the constituent components to those described below. The technical idea of the present invention can be subjected to a variety of alterations within the technical scope prescribed by the claims described in CLAIMS.

An embodiment of the present invention will now be described below with reference to the drawings.

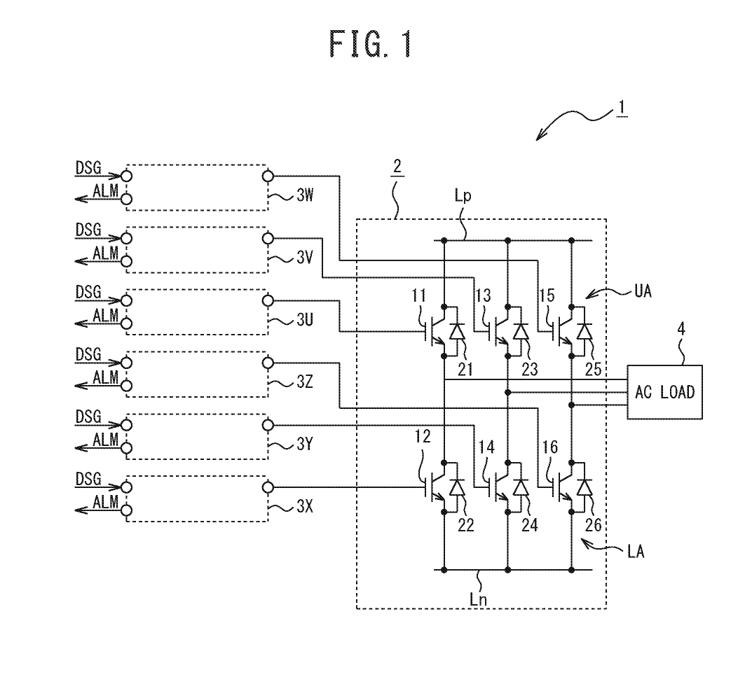

FIG. 1 is a block diagram illustrating an overall schematic structure of a power conversion device to which the present invention is applied. In the FIG. 1, a power conversion device 1 includes an inverter 2 configured to convert DC power to AC power and each phase driver circuit 3U to 3Z as a semiconductor element driving device configured to individually drive a semiconductor element of each phase (from U phase to Z phase) included in the inverter 2.

The inverter 2 includes insulated gate bipolar transistors (IGBTs) 11 to 16 as six semiconductor elements.

As to these IGBTs 11 to 16, a series circuit of the IGBTs 11 and 12, a series circuit of the IGBTs 13 and 14, and a series circuit of the IGBTs 15 and 16 are each connected in parallel between a positive-side line Lp and a negative-side line Ln connected to a DC power supply to receive DC power. Herein, free wheel diodes 21 to 26 are connected in inverse-parallel to the IGBTs 11 to 16, respectively.

Additionally, the IGBTs 11, 13, and 15, respectively, are used for U phase, V phase, and W phase to form an upper arm UA. In addition, the IGBTs 12, 14, and 16, respectively, are used for X phase, Y phase, and Z phase to form a lower arm LA. Furthermore, three-phase AC power is output from a connection point between the IGBTs 11 and 12, a connection point between the IGBTs 13 and 14, and a connection point between the IGBTs 15 and 16. The three-phase AC power is supplied to an AC load 4 such as an electric motor.

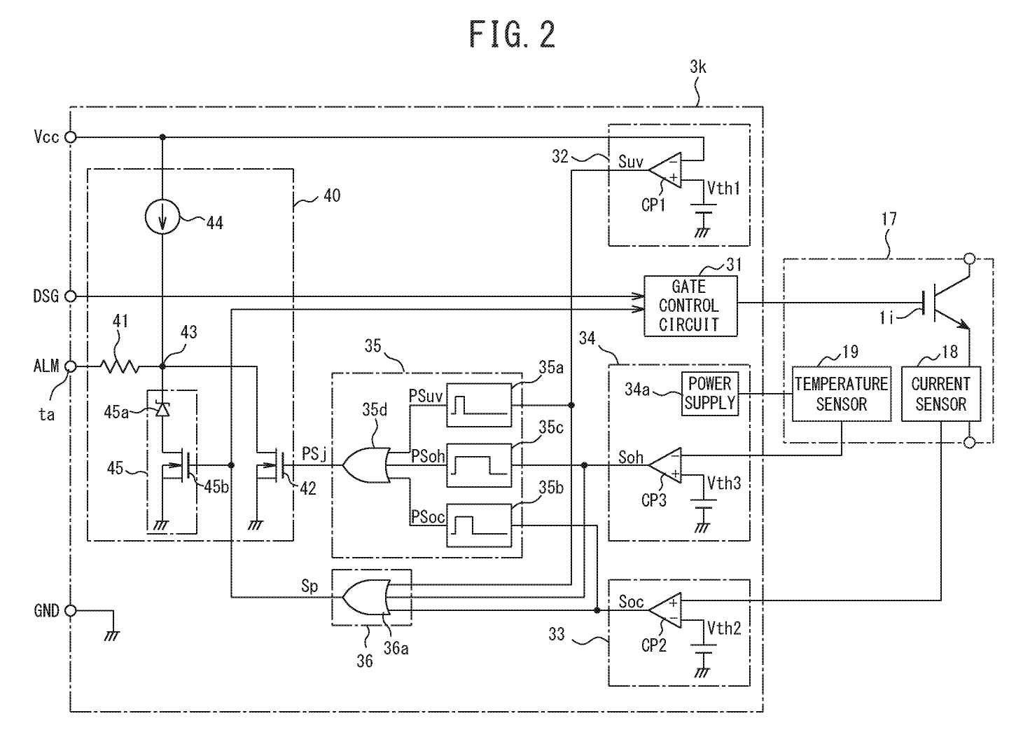

The IGBTs 11 to 16 are each arranged in a chip 17, as illustrated in FIG. 2. In the chip 17 are provided a current sensor 18 formed by a current sensing IGBT or a current sensing resistor configured to detect a current flowing between a collector and an emitter of an IGBT 1i (i=1 to 6) and a temperature sensor 19 formed by a temperature detection diode configured to detect a temperature in the chip.

As illustrated in FIG. 2, each phase driver circuit 3k (k=U to Z) includes a gate control circuit 31 configured to on/off control a gate of each IGBT 1i included in the inverter 2, a control voltage detection circuit 32, an overcurrent detection circuit 33, and a chip temperature detection circuit 34 as detection units. The control voltage detection circuit 32, the overcurrent detection circuit 33, and the chip temperature detection circuit 34 detect a low-voltage state, an overcurrent state, and an overheat state that are information necessary for protection operation for the IGBT 1i.

Additionally, each phase driver circuit 3U to 3Z includes a protection signal generation unit 35, a protection state monitoring unit 36, and a signal output unit 40.

As an operation signal DSG, a pulse width modulation (PWM) signal is input to the gate control circuit 31 from outside the driver circuit 3U to 3Z, and a protection state signal Sp output from the protection state monitoring unit 36 is also input thereto. The gate control circuit 31 outputs the operation signal DSG to the gate of the IGBT 1i when the protection state signal Sp is at low level, and stops the output of the operation signal DSG to the gate of the IGBT 1i when the protection state signal Sp is at high level.

The control voltage detection circuit 32 includes a comparator CP1 to which a control voltage Vcc (for example, 15 [V]) is input from outside the driver circuit 3U to 3Z, and also to which a low voltage threshold Vth1 is input. When the control voltage Vcc is below the low voltage threshold Vth1, the comparator CP1 outputs a low voltage detection signal Suv at high level that represents control voltage shortage to the protection signal generation unit 35 and the protection state monitoring unit 36. This allows detection of control voltage shortage, namely, detection of low voltage of IC power supply.

The overcurrent detection circuit 33 includes a comparator CP2 to which a current detection value (a voltage signal) detected by the current sensor 18 is input, and also to which an overcurrent threshold Vth2 is input. When the current detection value is above the overcurrent threshold Vth2, the comparator CP2 outputs an overcurrent detection signal Soc at high level that represents an overcurrent state to the protection signal generation unit 35 and the protection state monitoring unit 36. This allows detection of the overcurrent of the IGBT 1i.

The chip temperature detection circuit 34 includes a comparator CP3 to which a temperature detection value (a voltage signal) detected by the temperature sensor 19 is input, and also to which an overheat threshold Vth3 is input. When the temperature detection value is below the overheat threshold Vth3, the comparator CP3 outputs an overheat detection signal Soh at high level that represents an overheat state to the protection signal generation unit 35 and the protection state monitoring unit 36. This allows detection of the overheat state of the IGBT 1i.

It is noted that when the temperature sensor 19 is formed by a temperature detection diode, a power supply 34a in the chip temperature detection circuit 34 illustrated in FIG. 2 serves to supply a constant current to the diode.

The protection signal generation unit 35 includes a first one-shot circuit 35a, a second one-shot circuit 35b, and a third one-shot circuit 35c formed by one-shot circuits, and an OR gate 35d to which output pulses of these circuits are input.

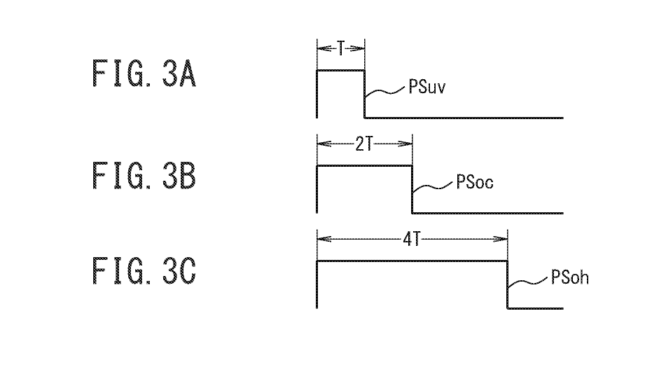

When the low voltage detection signal Suv at high level due to the detection of control voltage shortage, namely, low voltage of the IC power supply is input from the control voltage detection circuit 32, the first one-shot circuit 35a outputs a high level pulse signal PSuv having, as a pulse width, for example, a basic pulse width of T to the OR gate 35d, as illustrated in FIG. 3A. As the basic pulse width of T, for example, 2 [ms] can be employed.

Additionally, when the overcurrent detection signal Soc due to the detection of the overcurrent state of the IGBT 1i is input from the overcurrent detection circuit 33, the second one-shot circuit 35b outputs a pulse signal PSoc at high level having a pulse width of, for example, 2T to the OR gate 35d, as illustrated in FIG. 3B.

Furthermore, when the overcurrent detection signal Soh due to the detection of the overheat state of the IGBT 1i is input from the chip temperature detection circuit 34, the third one-shot circuit 35c outputs a pulse signal PSoh at high level having a pulse width of, for example, 4T to the OR gate 35d, as illustrated in FIG. 3C.

The OR gate 35d outputs a high level protection signal to the signal output unit 40 when any of the pulse signals PSuv, PSoc, and PSoh output from the first one-shot circuit 35a, the second one-shot circuit 35b, and the third one-shot circuit 35c is at high level.

Herein, the pulse width of a pulse signal PSj is from 2 to 8 [ms], which is sufficiently short. Accordingly, for example, even when, after occurrence of an overcurrent state, an overheat state occurs due to that, and two or more pulse signals PSj occur, the two or more pulse signals PSj are hardly simultaneously input. Thus, the protection signal generation unit 35 outputs to the signal output unit 40 a pulse signal PSj (as a protection signal) corresponding to any detection circuit 32 to 34 that has detected control voltage shortage, overcurrent, or an overheat state (i.e. any detection circuit 32 to 34 that has detected the necessity of protection operation) among the control voltage detection circuit 32, the overcurrent detection circuit 33, and the chip temperature detection circuit 34.

The protection state monitoring unit 36 includes an OR gate 36a to which the low voltage detection signal Suv output from the control voltage detection circuit 32, the overcurrent detection signal Soc output from the overcurrent detection circuit 33, and the overheat detection signal Soh output from the chip temperature detection circuit 34. The OR gate 36a outputs a high level protection state signal Sp to the gate control circuit 31 and the signal output unit 40 when any of the low voltage detection signal Suv, the overcurrent detection signal Soc, and the overheat detection signal Soh is at high level.

The signal output unit 40 includes a series circuit of a resistor 41 (a limit resistor) as a third resistor and an n-channel MOSFET 42 as a first switching element connected in series between an alarm signal output terminal ta and a ground. Herein, a drain of the MOSFET 42 is connected to the alarm signal output terminal ta via the resistor 41, a source thereof is connected to the ground, and a gate (a control terminal) thereof is connected to an output terminal of the OR gate 35d of the protection signal generation unit 35.

Then, one end of a constant current source 44 is connected to a control power supply input terminal tvi, and the other end thereof is connected to a connection point 43 between the resistor 41 and the MOSFET 42. The constant current source 44 supplies a constant current of, for example, 200 [μA] to the connection point 43.

Additionally, in the signal output unit 40, an intermediate voltage generation circuit 45 (a constant voltage circuit) is connected in parallel with the MOSFET 42. The intermediate voltage generation circuit 45 is formed by a series circuit of a Zener diode 45a and an n-channel MOSFET 45b as a second switching element.

A breakdown voltage Vmd of the Zener diode 45a is set to an intermediate voltage (for example, 7 [V]) between the control voltage Vcc and a ground potential GND. A cathode of the Zener diode 45a is connected to the connection point 43 between the resistor 41 and the MOSFET 42, and an anode thereof is connected to a drain of the MOSFET 45b. A source of the MOSFET 45b is connected to a ground, and a gate (a control terminal) thereof is connected to an output terminal of the OR gate 36a of the protection state monitoring unit 36 described above.

Thus, when the MOSFETs 42 and 45b are both in off-states, the connection point 43 has the control voltage Vcc, whereby the alarm signal output terminal ta has the control voltage Vcc that is a first level. On the other hand, when the MOSFET 42 is in an on-state, constant current from the constant current source 44 flows to the ground, so that regardless of the on- or off-state of the MOSFET 45b, the connection point 43 has the ground potential that is a second level, and the alarm signal output terminal ta also has the ground potential.

Alternatively, when the MOSFET 45b is in the on-state and the MOSFET 42 is in the off-state, the anode of the Zener diode 45a is grounded through the MOSFET 45b, so that the connection point 43 goes to an intermediate level between the first level and the second level, which is the breakdown voltage Vmd, and the alarm signal output terminal ta also goes to the intermediate level.

Accordingly, the alarm signal output terminal ta outputs an alarm signal ALM having three levels: the first level, the second level, and the intermediate level therebetween.

Next will be a description of operation of the power conversion device 1 of the present embodiment.

Now, assume that when each of detection values of currents flowing through the IGBTs 11 to 16 included in the inverter 2 is below the overcurrent threshold Vth2, it is normal; when a detection value of a temperature in the chip 17 having each IGBT 11 to 16 formed thereon is equal to or more than the overheat threshold Vth3, it is normal; and furthermore, when the control voltage Vcc (the IC power supply voltage) supplied to each driver circuit 3U to 3Z is above the low voltage threshold Vth1, it is normal.

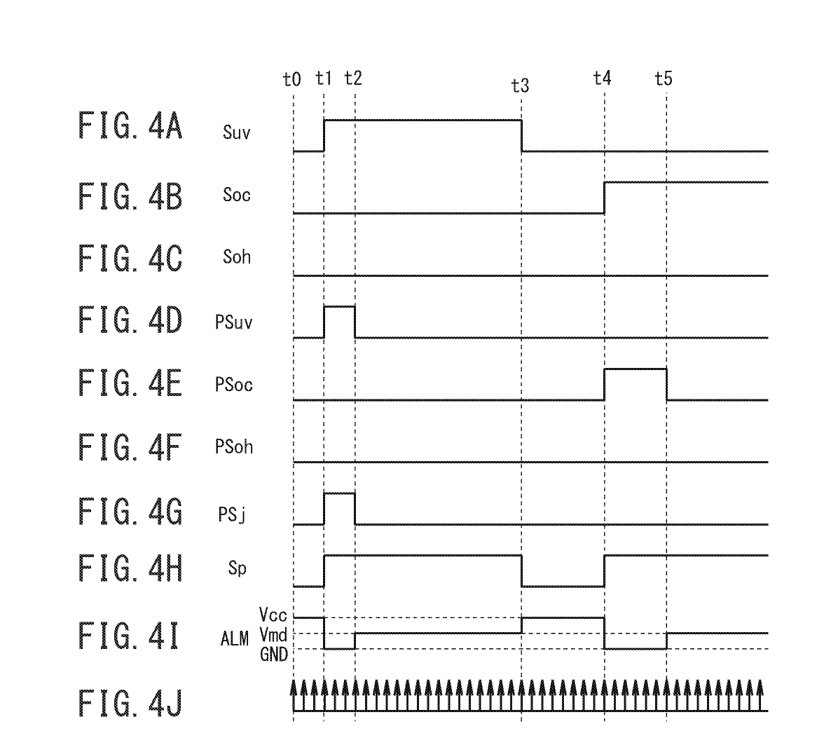

In this normal state, at a time point t0, the low voltage detection signal Suv output from the control voltage detection circuit 32 of each driver circuit 3U to 3Z, the overcurrent detection signal Soc output from the overcurrent detection circuit 33 thereof, and the overheat detection signal Soh output from the chip temperature detection circuit 34 thereof are all at low level, as illustrated in FIGS. 4A to 4C.

Due to that, as illustrated in FIGS. 4D to 4F, outputs of the first one-shot circuit 35a, the second one-shot circuit 35b, and the third one-shot circuit 35c of the protection signal generation unit 35 maintain low level. Accordingly, the protection signal PSj output from the OR gate 35d maintains low level, as illustrated in FIG. 4G, and the protection state signal Sp also maintains low level, as illustrated in FIG. 4H.

At this time, since the protection signal PSj output from the protection signal generation unit 35 maintains the low level, the MOSFET 42 of the signal output unit 40 maintains an off-state. Additionally, since the protection state signal Sp output from the protection state monitoring unit 36 also maintains the low level, the MOSFET 45b also maintains an off-state. Therefore, the potential of the connection point 43 goes to the first level that is the potential of the control voltage Vcc, whereby the alarm signal ALM output from the alarm signal output terminal ta goes to the potential of the control voltage Vcc representing the normal state, as illustrated in FIG. 4I.

Thus, in each driver circuit 3X to 3Z, since the protection state signal Sp is at the low level, the gate control circuit 31 supplies a gate signal corresponding to the operation signal DSG input from an external control device (not illustrated) to the gate of each IGBT 11 to 16, the inverter 2 converts the DC power to AC power, and the AC power is output to the AC load 4.

After that, at a time point t1 from a state where each phase IGBT 11 to 16 in the inverter 2 is in the normal state and the IC power supply voltage is normal, when there occurs a low voltage abnormality in which, for example, the control voltage Vcc that is the IC power supply voltage supplied to the driver circuit 3U that drives the U-phase IGBT 11 drops to equal or less than the low voltage threshold Vth1, the low voltage abnormality is detected by the control voltage detection circuit 32.

Then, the low voltage detection signal Suv at high level is supplied from the control voltage detection circuit 32 to the protection signal generation unit 35 and the protection state monitoring unit 36. Thus, a high level pulse signal PSuv having a pulse width of T is output from the first one-shot circuit 35a of the protection signal generation unit 35, as illustrated in FIG. 4D. In addition, simultaneously, the protection state signal Sp output from the protection state monitoring unit 36 is inverted from low level to high level, as illustrated in FIG. 4H.

Thus, the high level protection state signal Sp is supplied to the gate control circuit 31, whereby output of a gate driving signal from the gate control circuit 31 is stopped, and the IGBT 11 is turned off to be brought into a protected state.

At this time, since the protection signal PSj output from the protection signal generation unit 35 goes to high level, the MOSFET 42 of the signal output unit 40 is turned on. Therefore, the connection point 43 is connected to the ground through the MOSFET 42, whereby the potential of the connection point goes to the second level that is the ground potential GND. Due to this, the potential of the alarm signal ALM changes state from the first level to the second level (the ground potential GND) that represents being in the protection state due to the occurrence of the abnormality, as illustrated in FIG. 4I.

It is noted that at that time, since the protection state signal Sp output from the protection state monitoring unit 36 also goes to high level, the MOSFET 45b of the signal output unit 40 is also turned on. This allows the anode of the Zener diode 45a to be connected to the ground via the MOSFET 45b, whereas the potential of the connection point 43 is at the second level (the ground potential GND). Thus, the Zener diode 45a stops functioning as the intermediate voltage generation circuit.

After that, at a time point t2 at which a time corresponding to the pulse width of T has passed from the time point t1, the protection signal PSuv output from the first one-shot circuit 35a of the protection signal generation unit 35 returns from the high level to the low level, as illustrated in FIG. 4D. In response to this, the MOSFET 42 of the signal output unit 40 is turned off. Due to this, although the potential of the connection point 43 is about to rise up to the control voltage Vcc, the control voltage Vcc continues to be in the low voltage state at the time point t2, and the low voltage detection signal Suv output from the control voltage detection circuit 32 maintains the high level, as illustrated in FIG. 4A. Therefore, the protection state signal Sp output from the protection state monitoring unit 36 maintains the high level, as illustrated in FIG. 4H, so that the MOSFET 45b is maintained in the on-state. Thus, when a voltage applied to the Zener diode 45a becomes equal to or more than the breakdown voltage Vmd, the Zener diode 45a is electrically conducted, whereby the potential of the connection point 43 goes to the intermediate level that is the breakdown voltage Vmd. Accordingly, the alarm signal ALM output from the alarm signal output terminal ta goes to the intermediate level that is the breakdown voltage Vmd of the Zener diode 45a, as illustrated in FIG. 4I, which represents that the protection state is continuing due to the continuation of the abnormal state occurred.

After that, at a time point t3, when the control voltage Vcc supplied from outside returns to a normal voltage that is higher than the low voltage threshold Vth1, the low voltage detection signal Suv output from the control voltage detection circuit 32 returns from the high level to the low level, as illustrated in FIG. 4A. In response to this, the protection state signal Sp output from the protection state monitoring unit 36 also returns from the high level to the low level, as illustrated in FIG. 4H. This causes the gate control circuit 31 to output a gate driving signal in accordance with the operation signal DSG to the gate of the IGBT 1i, whereby the IGBT 1i returns to a normal operation state.

As a result, since the protection state signal Sp output from the protection state monitoring unit 36 also returns to the low level, the MOSFET 45b of the signal output unit 40 is also turned off. Therefore, the potential of the connection point 43 returns to the control voltage Vcc. Thus, the alarm signal ALM output from the alarm signal output terminal ta returns to the first level representing the normal state, which is the control voltage Vcc, as illustrated in FIG. 4I.

On the other hand, in the external control device, when the alarm signal ALM is input from the driver circuit 3k, a clock signal CP illustrated in FIG. 4J is counted while the alarm signal ALM is maintaining the second level that is the ground potential GND. Then, the counts and a time between pulses of the clock signal CP are multiplied together to calculate a cumulative time, and with the cumulative time, it can be detected that the alarm signal ALM is due to the low voltage detection signal Suv. In this manner, it can be easily determined that the type of the abnormality having occurred in the IGBT 1i is a low voltage abnormality. It is noted that the type of the abnormality detection circuit may be determined by the counts of the clock signal CP in a period of time in which the alarm signal ALM maintains the second level that is the ground potential GND.

In addition, in the external control device, detecting the voltage of the alarm signal ALM enables it to recognize the occurrence of an overcurrent abnormality or an overheat abnormality in the IGBT 1i or the occurrence of a low voltage state where the control voltage Vcc is less than the low voltage threshold Vth1, when the alarm signal ALM is at the second level. Alternatively, when the alarm signal ALM is at the intermediate level, it can be recognized that the state where the overcurrent abnormality or the overheat abnormality in the IGBT 1i has occurred or the state where the control voltage Vcc is in the low-voltage state is continuing.

Similarly, at a time point t4, when the overcurrent detection circuit 33 of a certain driver circuit 3k detects that a detection value of a collector current of the IGBT 1i included in the inverter 2 is equal to or more than the overcurrent threshold Vth2, the overcurrent detection circuit 33 outputs the overcurrent detection signal Soc at high level, as illustrated in FIG. 4B. The overcurrent detection signal Soc is supplied to the protection signal generation unit 35. This causes the second one-shot circuit 35b of the protection signal generation unit 35 to output the pulse signal PSoc having a pulse width of 2T at high level illustrated in FIG. 4E. Accordingly, the protection signal PSj illustrated in FIG. 4G is output from the OR gate 35d of the protection signal generation unit 35, and is supplied to the gate of the MOSFET 42 of the signal output unit 40. Thus, the MOSFET 42 is turned on, whereby, as illustrated in FIG. 4I, the alarm signal ALM that is at the second level during a period of time corresponding to the pulse width of 2T of the protection signal PSoc is output from the alarm signal output terminal ta to the external control device.

Thus, in the external control device, the occurrence of an overcurrent abnormality can be recognized since the pulse width of the second level, which is the ground potential GND, of the alarm signal ALM is 2T. Additionally, the alarm signal ALM is maintained at the intermediate level that is the breakdown voltage Vmd until the protection state due to the overcurrent abnormality is eliminated after passage of the time corresponding to the pulse width of 2T. This enables the external control device to recognize that the protection operation due to the overcurrent abnormality is continuing even after the protection signal PSoc has returned from the high level to the low level.

Similarly, when the chip temperature detection circuit 34 of the certain driver circuit 3k detects that the detection value of the temperature in the chip 17 incorporating the IGBT 1i included in the inverter 2 is less than the overheat threshold Vth3, the chip temperature detection circuit 34 outputs the overheat detection signal Soh at high level. The overheat detection signal Soh is supplied to the protection signal generation unit 35. This causes the third one-shot circuit 35c of the protection signal generation unit 35 to output the protection signal PSoh. Accordingly, the MOSFET 42 of the signal output unit 40 is turned on, whereby the alarm signal ALM at the second level corresponding to the pulse width of 4T of the pulse signal PSoh is output to the external control device.

Thus, in the external control device, the occurrence of an overheat abnormality can be recognized since the pulse width of the alarm signal ALM at the second level is 4T. Additionally, the voltage of the alarm signal ALM is maintained at the intermediate level that is the breakdown voltage Vmd until the protection operation due to the overheat abnormality is eliminated after passage of a time corresponding to the pulse width of 4T, so that the external control device can recognize that the overheat abnormality is continuing even after the protection signal PSoh has returned from the high level to the low level.

It is noted that while the embodiment has described the case where the power semiconductor elements were IGBTs, the invention is not limited thereto, and the power semiconductor elements can be formed by another type of power semiconductor element, such as SiC-IGBT, MOSFET, or SiC-MOS.

In addition, while the embodiment has described the case where the n-channel MOSFETs were applied as the MOSFETs of the signal output unit 40, p-channel MOSFETs can also be applied. In this case, the first level of the alarm signal ALM is the ground potential GND, and the second level thereof is the control voltage Vcc, whereas the intermediate level remains to be the breakdown voltage Vmd. At this time, output signals of the protection signal generation unit 35 and the protection state monitoring unit 36 may be supplied to p-channel MOSFETs 42 and 45b, respectively, via a logic inversion circuit.

Additionally, while the embodiment has described the case where the Zener diode 45a included in the intermediate voltage generation circuit 45 was connected to the connection point 43 side, the Zener diode 45a may be connected to the ground side of the MOSFET 45b. Furthermore, as an alternative to the Zener diode 45a, a resistor (a second resistor) may be applied.

Additionally, as an alternative to the constant current source 44, a resistor (a pull-up resistor) can be applied. Furthermore, the resistor 41 may be omitted.

In addition, the pulse widths of the first one-shot circuit 35a, the second one-shot circuit 35b, and the third one-shot 35c of the protection signal generation unit 35 are not limited to T, 2T, and 4T, and can be set to optional different pulse widths as long as the type of an abnormal state can be identified.

Additionally, there may be provided an input selection circuit configured, when one abnormality detection signal is input to the protection signal generation unit 35, to inhibit inputs of other abnormality detection signals for a predetermined period of time.

Furthermore, signals to the gates of the MOSFETs 42 and 45b may be interchangeable. In this case, information relating to the states represented by the intermediate level and the second level will be interchanged.

### REFERENCE SIGNS LIST

1: Power conversion device
2: Inverter
3U to 3Z: Driver circuit
4: AC load
11 to 16: IGBT
17: Chip
18: Current sensor
19: Temperature sensor
21 to 26: Free wheel diode
UA: Upper arm
LA: Lower arm
31: Gate control circuit
32: Control voltage detection circuit
33: Overcurrent detection circuit
34: Chip temperature detection circuit
35: Protection signal generation unit
35a: First one-shot circuit
35b: Second one-shot circuit
35c: Third one-shot circuit
35d: OR gate
36: Protection state monitoring unit
36a: OR gate
40: Signal output unit
41: Resistor
42: MOSFET
43: Connection point
44: Constant current source
45: Intermediate voltage generation circuit
45a: Zener diode
45b: MOSFET
PSj: Protection signal
Sp: Protection state signal

1. A semiconductor element driving device comprising:
a plurality of detection units configured to detect information necessary for protection operation for a semiconductor element included in a power conversion device;
a protection signal generation unit configured to generate a protection signal having a pulse width different according to each of the plurality of detection units when the plurality of detection units detect the information necessary for the protection operation;
a protection state monitoring unit configured to generate a protection state signal while any of the plurality of detection units is detecting the information necessary for the protection operation; and
a signal output unit configured to output an alarm signal, the alarm signal changing from a first level to a second level when the protection signal and the protection state signal are input, and changing to an intermediate level between the first level and the second level when the input of the protection signal is stopped.

2. The semiconductor element driving device according to claim 1, wherein the protection signal generation unit includes:
a plurality of one-shot circuits configured to receive detection signals of the plurality of detection units, respectively; and
an OR gate configured to receive output signals of the plurality of one-shot circuits and generate the protection signal, and
each of the plurality of one-shot circuits generates a pulse having a pulse width depending on one of the plurality of detection units from which a detection signal is received.

3. The semiconductor element driving device according to claim 1, wherein the protection state monitoring unit includes an OR gate configured to receive detection signals of the plurality of detection units and output the protection state signal.

4. The semiconductor element driving device according to claim 1, wherein
the signal output unit includes a first switching element connected between an output terminal and a ground, an intermediate voltage generation circuit including a second switching element connected in parallel with the first switching element, and a constant current source or a pull-up resistor connected to a terminal on the output terminal side of the first switching element,
the protection signal is input to a control terminal of the first switching element, and
the protection state signal is input to a control terminal of the second switching element.

5. The semiconductor element driving device according to claim 4, wherein the intermediate voltage generation circuit includes a Zener diode or a second resistor connected in series with the second switching element.

6. The semiconductor element driving device according to claim 4, comprising a third resistor between the output terminal and the first switching element.
